(19) United States
(12) Patent Application Publication
(10) Pub. No.: US 2016/0307640 A1
(43) Pub. Date: Oct. 20, 2016

(54) METHOD AND DEVICE FOR PROGRAMMING MEMORY CELLS OF THE ONE-TIME-PROGRAMMABLE TYPE

(71) Applicant: STMicroelectronics SA, Montrouge (FR)

(72) Inventors: Philippe Candelier, Saint Mury (FR); Antoine Benoist, Bernin (FR); Stephane Denorme, Crolles (FR); Joel Damiens, Le Touvet (FR)

(73) Assignee: STMicroelectronics SA, Montrouge (FR)

(21) Appl. No.: 14/956,963

(22) Filed: Dec. 2, 2015

(30) Foreign Application Priority Data
Apr. 15, 2015 (FR) 1500786

(51) Int. Cl. G11C 17/16; G11C 17/18

(52) U.S. Cl. CPC G11C 17/165; G11C 17/18

(57) ABSTRACT

A memory cell of the one-time-programmable type is programmed by application of a programming voltage having a value sufficient to obtain a breakdown of a dielectric of a capacitor within the cell. A programming circuit generates the programming voltage as a variable voltage that varies as a function of a temperature (T) of the cell. In particular, the programming voltage varies based on a variation law decreasing as a function of the temperature.

### PRIORITY CLAIM

This application claims priority to French Application for Patent No. 1500786 filed Apr. 15, 2015, the disclosure of which is incorporated by reference.

### TECHNICAL FIELD

Various embodiments of the invention and their implementation relate to the non-volatile memory cells of the one-time-programmable type, known by those skilled in the art under the acronym OTP (One Time Programmable) and, more particularly, the programming of such memory cells.

### BACKGROUND

Conventionally, a memory cell of the one-time-programmable type operates as a fuse or an anti-fuse whose state is modified in an irreversible manner, for example by breakdown of a dielectric, by applying a high programming voltage to the memory cell, in such a manner that the memory cell goes from a non-conducting state to a conducting state, which amounts to changing its resistance.

For example, a memory cell of the one-time-programmable type in the form of an anti-fuse generally comprises a capacitor having a layer of dielectric between its two electrodes. This capacitor may be formed by a MOS transistor whose source and drain are connected. Depending on the applied programming voltage and the programming time, a conducting channel can be obtained which passes completely through the layer of dielectric of the capacitor, a phenomenon known by those skilled in the art under the term “Hard Breakdown”.

As a result, this conducting channel changes definitively the state of the capacitor which goes from non-conducting to conducting, in other words this structure defines a resistor of the memory cell whose resistance is modified by programming. The logical value of the memory cell, for example initially equal to “0”, then becomes “1” when the conducting channel created passes completely through the layer of dielectric of the capacitor.

In order to minimize the power consumption and to maximize the programming efficiency, the programming voltage is applied within a very short lapse of time of the order of tens of nanoseconds and the value of the programming electric field may go as high as 35 MV/cm.

However, the applied programming voltage is generally chosen for a worst case scenario and remains constant during the whole programming process irrespective of the temperature of the integrated circuit containing the memory cells. The applied programming voltage is therefore often higher than that needed to break down the layer of dielectric of the capacitor within a given programming time.

This consequently results in a high leakage current once the conducting channel is under formation then completely created during the programming operation.

Furthermore, circuits around the memory cells that need to be preserved are de facto subjected to a high stress during the application of the programming voltage which risks damaging them.

This phenomenon is even more critical for high densities of memory cells which is the case for advanced CMOS technologies.

### SUMMARY

According to one embodiment and its implementation, an improvement in the efficiency of programming of memory cells of the OTP type is provided, while at the same time limiting as far as possible the stress suffered by components close to these memory cells.

In this respect, the inventors have observed, notably by measurement, that for a given programming time, the programming voltage to be applied to a memory cell of the OTP type in order to break down its dielectric follows a law of decreasing variation with temperature owing to the thermal activation.

More precisely, it has been observed that this variation law could be advantageously approximated by a decreasing affine voltage-temperature law.

The inventors have furthermore observed that such an affine law formed a good approximation to the 1^{st} order of a model of time dependency of the breakdown of a dielectric, commonly known by those skilled in the art under the acronym TDDB (for Time Dependent Dielectric Breakdown) but which needs to be adapted for high-voltage applications.

Thus, according to one aspect, a method is provided for programming of at least one memory cell of the one-time-programmable type comprising a capacitor, comprising the generation of a programming voltage and the application of this programming voltage to the at least one memory cell in such a manner as to obtain a breakdown of the dielectric of the capacitor.

According to a general feature of this aspect, the method comprises a variation of the programming voltage as a function of the temperature of the at least one memory cell based on a decreasing variation law as a function of the temperature.

The variation law may be a decreasing affine voltage-temperature law which is, for example, an approximation of a relationship between a voltage applied to the dielectric, the temperature and the time after which the breakdown of the dielectric occurs, the relationship being taken from a model of time dependency of the breakdown of a dielectric.

This variation law may be advantageously obtained using a band-gap voltage source generating a band-gap voltage and, internally, a current proportional to the absolute temperature of the memory cell.

According to another aspect, an integrated circuit is provided comprising an electronic device designed to program at least one memory cell of the one-time-programmable type comprising a capacitor, comprising a module configured for generating a programming voltage designed to break down the dielectric of the capacitor.

According to a general feature of this other aspect, the module is configured for generating a programming voltage varying with the temperature of the memory cell according to a decreasing variation law as a function of the temperature.

The module may advantageously be configured for generating the programming voltage varying according to the variation law which is an approximation of a relationship between a voltage applied to the dielectric, the temperature and the time after which the breakdown of the dielectric occurs, the relationship being taken from a model of time dependency of the breakdown of a dielectric.

Furthermore, the module is, for example, configured for generating the programming voltage varying according to the variation law which is a decreasing affine voltage-temperature law.

According to one embodiment, the module comprises generation means configured for generating an intermediate reference voltage varying according to the variation law, and a charge pump configured for generating the programming voltage starting from the intermediate reference voltage.

Since the intermediate reference voltage follows the variation law, the programming high voltage generated by the charge pump follows the same variation law.

One particularly advantageous way of generating a decreasing affine voltage-temperature variation law is, as indicated hereinbefore, to use a band-gap voltage source which allows a band-gap voltage to be delivered that is constant with respect to temperature (which will allow the constant coefficient of the affine law to be obtained) and which furthermore contains an internal core generating a current proportional to temperature (which will allow the coefficient of proportionality of the affine law to be obtained after processing).

Thus, according to one embodiment, the generation means comprise: a band-gap voltage source configured for generating a band-gap voltage and a first current proportional to the absolute temperature of the memory cell, an output stage connected to the band-gap voltage source and configured for generating a first elementary current independent of the absolute temperature from the band-gap voltage and a second elementary current proportional to the absolute temperature starting from the first current, subtraction means configured for subtracting the second elementary current from the first elementary current so as to obtain a second current inversely proportional to the absolute temperature, and means for transforming the second current into the intermediate reference voltage.

The integrated circuit can advantageously incorporate a memory plane of cells of the one-time-programmable type and decoding means for selectively applying the programming voltage to at least one cell of the memory plane.

### BRIEF DESCRIPTION OF THE DRAWINGS

Other advantages and features of the invention will become apparent upon examining the detailed description of non-limiting embodiments and their implementation, and the appended drawing in which:

FIGS. 1 to 6 relate to embodiments and their implementation.

### DETAILED DESCRIPTION

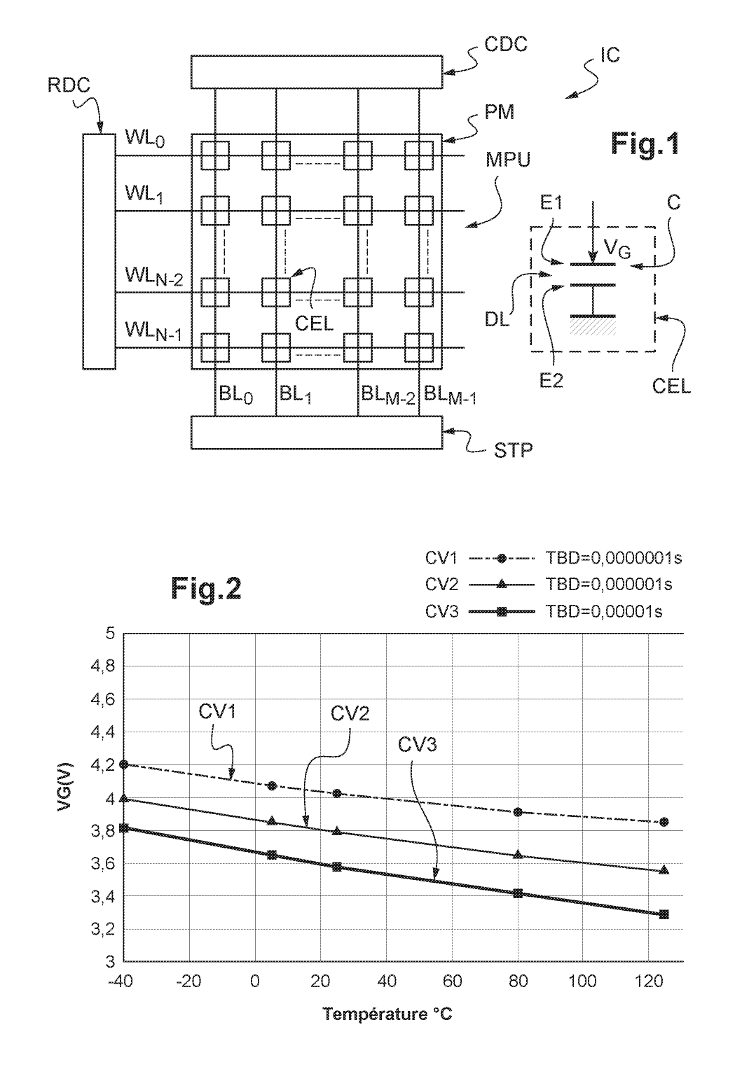

In FIG. 1, an integrated circuit IC is illustrated very schematically comprising a non-volatile memory device of the one-time-programmable type MPU.

This memory device MPU comprises a matrix memory plane PM comprising N rows and M columns of memory cells CEL.

Each memory cell is connected to a word-line WL and to a bit-line BL.

As shown schematically on the right-hand side of FIG. 1, each cell comprises a capacitor C having an electrode E2 that is designed to be connected to ground, and another electrode E1 that is designed to receive a programming voltage V_{G} for a given programming time in such a manner as to break down the dielectric DL.

Of course, as is well known to those skilled in the art, each memory cell is in fact accessible via an access transistor, typically an NMOS access transistor whose gate is connected to the word-line WL, whose drain is connected to the electrode E2 and whose source is connected to the bit-line BL. However, for the sake of simplification, this access transistor is not shown on the right-hand side of FIG. 1.

The decoding of the word-lines WL is carried out by a row decoder RDC and the decoding of the bit-lines BL is carried out by a column decoder CDC.

The matrix memory plane PM is furthermore connected to a programming voltage source STP which supplies the programming voltage V_{G} for the memory cells CEL. A charge pump is often provided within the programming voltage source STP in order to obtain a high programming voltage V_{G}.

Depending on the desired granularity, the memory plane may be programmed by bit, or else by word (several cells of the same row and situated over several bit-line columns form a digital word), or alternatively by “memory page” (several memory words simultaneously).

As illustrated in FIG. 2, for a given programming time T_{BD} and a given surface area of the capacitor, the programming voltage V_{G} decreases as a function of the temperature of the memory cell. Three variation curves CV1, CV2, CV3 are shown in this figure for three different values of the programming time T_{BD} (10⁻⁵ s, 10⁻⁶ s, 10⁻⁷ s). Although these curves were able to be obtained by physical measurements on a memory cell, it can be seen that these curves also correspond to simulation results associated with a model of time dependency of the breakdown of a dielectric adapted to high voltages.

More precisely, according to the model, the programming voltage VG to be applied for the time T_{BD} to break down the dielectric varies as a function of temperature according to the variation law:

$${V}_{G} = \frac{\begin{matrix}Ln ( {T}_{BD} ) - Ln ( \frac{{e}^{L n ( {A}_{1} )} \cdot {( \frac{{S}_{ref}}{S} )}^{\frac{1}{β}}}{{V}_{ref}^{AT + B β - K}} ) + \\ \frac{b}{k} ( \frac{1}{T} - \frac{1}{{T}_{ref}} ) + ( - AT - B β + K ) ( Ln ( 5 ) - 1 )\end{matrix}}{\frac{AT + B β - K}{5} - \frac{a}{k} ( \frac{1}{T} - \frac{1}{{T}_{ref}} )}$$

in which:

lnA1 is a constant representing the ordinate at the origin in the logarithmic coordinate system;

β is a variability parameter (slope of the Weibull distribution of the times to the breakdown, called form parameter);

V_{ref} the reference voltage at which this variation law is calibrated;

S is the gate surface area of an MOS capacitor;

S_{ref} is the reference surface area at which this variation law has been calibrated;

T_{ref} is the reference temperature at which the variation law has been calibrated;

k is the Boltzmann's constant; and

a, b, A, B and K are constants extracted by linear regression.

By an approximation of the 1^{st} order, this variation law may be considered as a decreasing affine voltage-temperature law (V_{G}=−C1T+C2).

With regard to the above, a programming voltage source STP will now be described in order to take into account this decreasing affine variation law of the programming voltage as a function of the temperature.

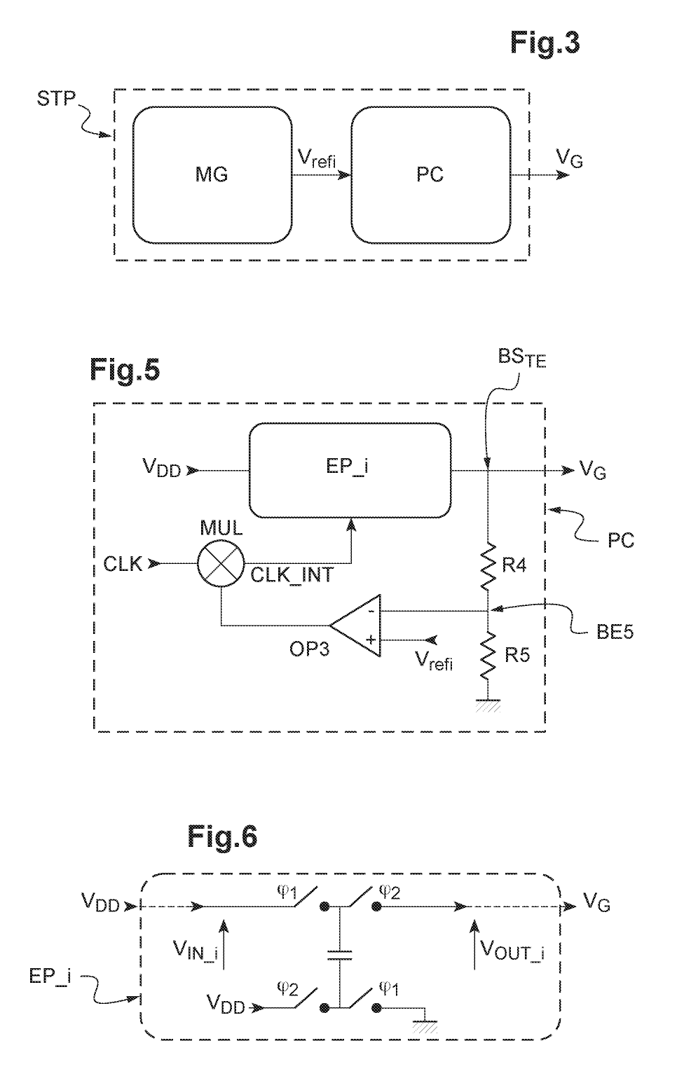

FIG. 3 illustrates schematically the structure of the programming voltage source STP. It comprises, for example, generation means MG configured for generating an intermediate reference voltage V_{refi} which varies according to the decreasing affine variation law, and a charge pump PC configured for generating the programming voltage V_{G} starting from the intermediate reference voltage V_{refi}.

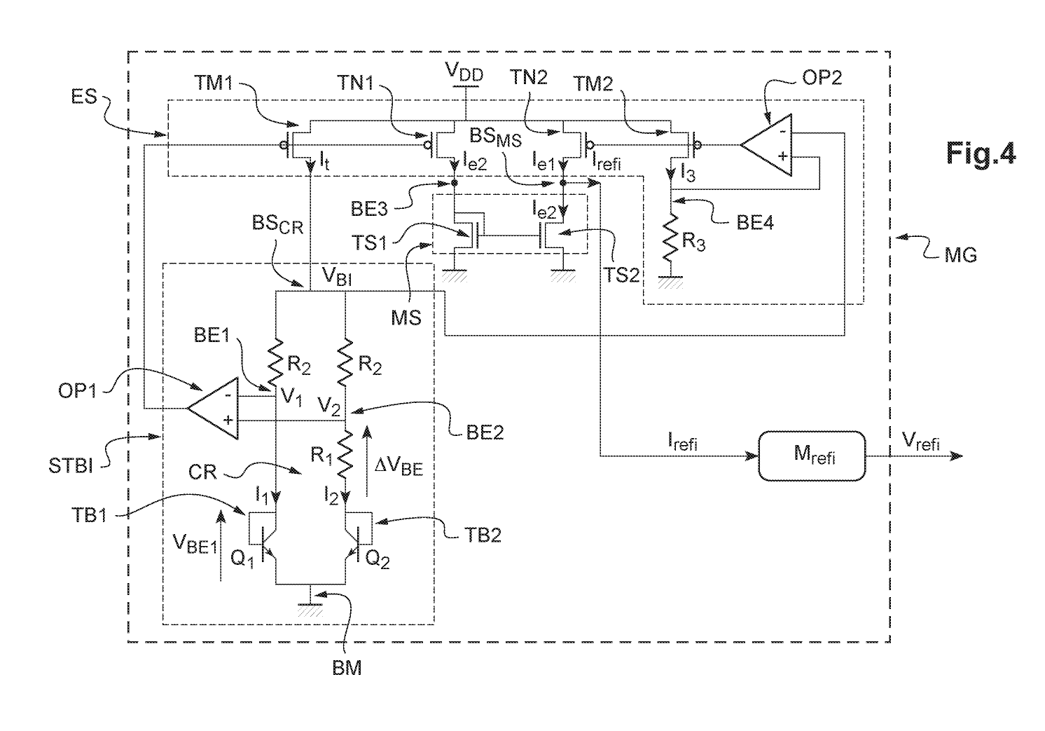

As illustrated in FIG. 4, the generation means MG advantageously comprise a band-gap voltage source STBI configured for generating a band-gap voltage V_{BI} at the output and, internally, a first current I₂ proportional to the absolute temperature of the memory cell.

The band-gap voltage source STBI illustrated in FIG. 4 comprises for example a conventional core circuit CR with a reference band-gap voltage arranged so that, when the voltages V1 and V2 at its two terminals BE1 and BE2 are equalized, one of its branches has the internal current I₂ flowing through it which is proportional to the absolute temperature, well known by those skilled in the art under the acronym Iₚₜₐₜ (“Proportional To Absolute Temperature”).

The core circuit CR here comprises a first NPN bipolar transistor, referenced TB1, configured as a diode and connected in series between the input terminal BE1 and a terminal BM connected to a reference voltage, here ground.

The core circuit CR further comprises a second NPN bipolar transistor, referenced TB2, configured as a diode and connected in series with a first resistor R1 between the input terminal BE2 and the terminal BM connected to ground.

The input terminals BE1 and BE2 are respectively connected to the output terminal BS_{CR} via a second resistor R2.

The band-gap voltage source STBI furthermore comprises an operational amplifier OP1 having its negative and positive inputs respectively connected to the terminals BE1 and BE2 in order to equalize the voltages V1 and V2, and its output connected to the output terminal BS_{CR} through transistor TM1.

When the voltages V1 and V2 are equalized by means of the operational amplifier OP1, as is well known by those skilled in the art, the internal current I₂ flowing through the resistor R1 is proportional to the absolute temperature and equal to kTln(Q1/Q2)/qR1, where k represents Boltzmann's constant, T the absolute temperature, q the charge of an electron, Q1 the size of the bipolar transistor TB1, Q2 the size of the bipolar transistor TB2, and ln the Napierian logarithmic function.

It should be noted that the size Q1 and the size Q2 are different and their ratio Q1/Q2 is chosen in such a manner that the density of current flowing through the transistor TB1 is different from the density of current flowing through the transistor TB2, whereas the current I₁ flowing through the transistor TB1 is equal to the current I₂ flowing through the transistor TB2. It would of course be equally possible to use a transistor TB2 and x transistors TB1 in parallel (where x is an integer), all of the same size as that of the transistor TB2.

The output voltage V_{BI} is equal to the sum of the voltage on the resistor R2 and the base-emitter voltage V_{BE1} of the transistor TB1. As the current I₁ is equal to the current I₂, the voltage on the resistor R2 is equal to R2*ΔV_{BE}/R1 which is proportional to the temperature. As regards the voltage V_{BEI}, it contains a constant term equal to the band-gap voltage (around 1.205 volts) and another term inversely proportional to the temperature.

As a consequence, by correctly choosing the ratio R2/R1, the term dependent on the temperature of the voltage V_{BI} can be cancelled. The voltage V_{BI} is equal to the band-gap voltage 1.205 volts and considered as independent of the absolute temperature.

As illustrated in FIG. 4, the generation means MG may further comprise an output stage ES connected to the band-gap voltage source STBI via the output terminal BS_{CR}.

This stage ES is configured for generating a first elementary current Iₑ₁ independent of the absolute temperature starting from the band-gap voltage V_{BI} and a second elementary current Iₑ₂ proportional to the absolute temperature from the first current I₂.

The means MG also comprise subtraction means MS configured for subtracting the second elementary current Iₑ₂ from the first elementary current Iₑ₁ in such a manner as to obtain a second current I_{refi} inversely proportional to the absolute temperature.

Means M_{refi} are also provided for transforming the second current I_{refi} into the intermediate reference voltage V_{refi}.

The output stage ES comprises a first current copying means comprising two transistors PMOS TM1 and TN1 having their sources mutually connected to the power supply voltage V_{DD}, their gates mutually connected to the output of the operational amplifier OP1. The drain of the transistor TM1 is connected to the output terminal BS_{CR} and the drain of the transistor TN1 is connected to the input terminal BE3 of the subtraction means MS.

The drain current It of the transistor TM1 is equal to the sum of the currents I₁ and I₂. The elementary current Iₑ₂ coming from the transistor TN1 is proportional to the current Iₜ according to the equation I₂=Iₜ*N1/M1, where N1 and M1 are the ratios of channel width and length of the transistors TN1 and TM1.

As a consequence, the elementary current Iₑ₂ is also proportional to the temperature as are I₁ or I₂.

The output stage ES furthermore comprises an operational amplifier OP2, configured as a follower, whose inverting input is connected to the output terminal BS_{CR}. The non-inverting input is connected to a terminal BE4 connected to ground via a resistor R3 and the output of the amplifier OP2 is connected to the gates of the transistors PMOS TN2 and TM2 which form a second current copying means.

The sources of the transistors TN2 and TM2 are mutually connected to the voltage V_{DD}. The drains of the transistors TN2 and TM2 are respectively connected to the output terminal BS_{MS} of the subtraction means MS and to the terminal BE4.

As was described hereinbefore, the voltage V_{BI} is configured to be constant and independent of the temperature. By virtue of the amplifier OP2, the voltage on the terminal BE4 is equal to V_{BI} and is also constant and independent of the temperature.

As a consequence, the current I₃ flowing through the resistor R3, equal to V_{BI}/R3, is also independent of the temperature.

Thus, an elementary current Ie1 may be obtained on the drain of the transistor TN2 starting from the band-gap voltage V_{BI} which is equal to I₃*N2/M2, where N2 and M2 are the ratios of width and of length of channel of the transistors TN2 and TM2. This current Iₑ₁ is de facto independent of the absolute temperature.

The subtraction means MS comprise, for example, a current mirror comprising two transistors NMOS TS1 and TS2. The drains of the transistors TS1 and TS2 are respectively connected to the input terminal BE3 and to the output terminal BS_{MS} and their sources are mutually connected to ground. The gates of the transistors TS1 and TS2 are mutually connected to the drain of the transistor TS1.

Accordingly, the current flowing in the transistor TS2 towards ground is equal or substantially equal to the current Iₑ₂ and the output current I_{refi} delivered at the output terminal BS_{MS} is therefore equal to Iₑ₁−Iₑ₂.

Since the current Iₑ₁ is constant and the current Iₑ₂ is proportional to the temperature, the intermediate reference current I_{refi} is inversely proportional to the temperature and is equal to −A1T+A2.

The values of the coefficients A1 and A2 are adjustable via the sizes N1, N2, M1 and M2 of the transistors TN1, TN2, TM1 and TM2.

The intermediate reference current I_{refi} is subsequently delivered to the means M_{refi}, which comprise for example a resistor R, for transforming the current I_{refi} into the intermediate reference voltage V_{refi}, which is decreasing as a function of temperature according to an affine law: V_{refi}=−A1RT+A2R.

In order to generate the programming voltage V_{G} as a high voltage for the breakdown of the dielectric of the memory cells CEL, a charge pump PC is used within the programming voltage source STP and is illustrated in FIGS. 5 and 6.

The structure of a charge pump is conventional and known per se and FIGS. 5 and 6 only illustrate one non-limiting exemplary embodiment.

The intermediate reference voltage V_{refi} is delivered to the positive input of a operational amplifier OP3. The negative input of this operational amplifier OP3 is connected to an input terminal BE5. Two resistors R4 and R5 are respectively connected between the output terminal BS_{TE} of the charge pump PC and the terminal BE5 and between the terminal BE5 and ground. The output of the operational amplifier OP3 is connected to an input of a multiplier MUL which furthermore receives a clock signal CLK in order to deliver an internal clock signal to the charge pump stages.

The pump stages EP_i receive the power supply voltage V_{DD} and the internal clock signal CLK_INT as input signals for generating the programming voltage V_{G} equal to V_{refi}*(R4+R5)/R5 at the output terminal BS_{TE}.

FIG. 6 illustrates a pump stage EP_i.

In a first phase φ1, controlled by the internal clock signal, the input voltage Vin_i of the pump stage EP_i (which is equal to the output voltage of the preceding pump stage) charges a pump capacitor. For the first pump stage EP, the input voltage is the power supply voltage V_{DD}.

In a second phase φ2, also controlled by the internal clock signal CLK_INT, the capacitor is connected between the power supply voltage VDD and the output of the stage. If the leakage of the capacitor is ignored, the output voltage of each pump stage EP is increased by the voltage due to the discharging of the capacitor.

By multiplying the pump stages EP_i, a high voltage can be obtained at the output of the pump stages EP_i.

The last stage delivers the programming voltage V_{G} which is inversely proportional to the absolute temperature T of the memory cells CEL and follows a decreasing affine voltage-temperature law.

Depending on the desired programming time and on the corresponding affine law V_{G}=−C1T+C2, the source STP will be calibrated accordingly by an adjustment of the various aforementioned parameters in order to obtain the desired values of the coefficients C1 and C2.

The invention thus advantageously allows the voltage for programming cells OTP of an integrated circuit installed in a product whose temperature can vary in operation to be modulated in real time.

1. A method for programming a one-time-programmable type memory cell comprising a capacitor, said method comprising:
generating a programming voltage; and
applying the programming voltage to the one-time-programmable type memory cell in such a manner as to obtain a breakdown of a dielectric of the capacitor;
wherein the programming voltage varies as a function of a temperature of the one-time-programmable type memory cell based on a variation law decreasing as a function of the temperature.

2. The method according to claim 1, wherein the variation law is an approximation of a relationship between a voltage applied to the dielectric, the temperature and a time after which the breakdown of the dielectric occurs.

3. The method according to claim 2, wherein said relationship is taken from a model of time dependency of the breakdown of a dielectric.

4. The method according to claim 1, wherein the variation law is a decreasing affine voltage-temperature law.

5. An integrated circuit, comprising:
an electronic device configured to program a one-time-programmable type memory cell comprising a capacitor, comprising:
a circuit configured to generate a programming voltage designed to break down a dielectric of the capacitor, said programming voltage varying with a temperature of the a one-time-programmable type memory cell according to a variation law decreasing as a function of the temperature.

6. The integrated circuit according to claim 5, wherein the variation law is an approximation of a relationship between a voltage applied to the dielectric, the temperature and a time after which the breakdown of the dielectric occurs.

7. The integrated circuit according to claim 6, where said relationship is taken from a model of time dependency of the breakdown of a dielectric (TDDB).

8. The integrated circuit according to claim 5, wherein the programming voltage varies according to the variation law which is a decreasing affine voltage-temperature law.

9. Integrated circuit according to claim 5, wherein the circuit comprises:
means for generating an intermediate reference voltage varying according to the variation law, and
a charge pump configured for generating the programming voltage starting from the intermediate reference voltage.

10. The integrated circuit according to claim 9, wherein said means for generating comprise:
a band-gap voltage source configured to generate a band-gap voltage and a first current proportional to the absolute temperature of the memory cell,
an output stage connected to the band-gap voltage source and configured to generate a first elementary current independent of the absolute temperature from the band-gap voltage and a second elementary current proportional to the absolute temperature starting from the first current,
a subtraction circuit configured to subtract the second elementary current from the first elementary current in such a manner as to obtain a second current inversely proportional to the absolute temperature, and
a transforming circuit configured to transform the second current into the intermediate reference voltage.

11. The integrated circuit according to claim 5, wherein said one-time-programmable type memory cell is within a memory plane including a plurality of one-time-programmable type memory cells, and further including a decoding circuit for selectively applying the programming voltage to a selected one or more of the one-time-programmable type memory cells of the memory plane.

12. An integrated circuit, comprising:
a one-time-programmable type memory cell including a capacitor with a dielectric;
a programming circuit configured to program the one-time-programmable type memory cell by applying a programming voltage so as to breakdown the dielectric of the capacitor;
wherein the programming voltage is a variable voltage that decreases as a function of a temperature of the one-time-programmable type memory cell.

13. The integrated circuit of claim 12, wherein the programming circuit comprises:
a band-gap circuit configured to generate a band-gap voltage and a first current proportional to absolute temperature;
a first current generator configured to generate from the band-gap voltage a first elementary current independent of absolute temperature;
a second current generator configured to generate from the first current a second elementary current proportional to the absolute temperature;
a circuit configured to determine a difference between the first and second elementary currents and generate the programming voltage from said difference.

14. The integrated circuit of claim 13, wherein said circuit comprises:
a subtraction circuit configured to subtract the second elementary current from the first elementary current to obtain a second current inversely proportional to the absolute temperature, and
a transforming circuit configured to transform the second current into an intermediate reference voltage.

15. The integrated circuit of claim 14, wherein said circuit further comprises a charge pump circuit configured to generate the programming voltage from the intermediate reference voltage.

16. The integrated circuit of claim 12, wherein the variable programming voltage varies in accordance with a decreasing affine voltage-temperature law.
